(19) United States
(12) Patent Application Publication
(10) Pub. No.: US 2025/0260397 A1
(43) Pub. Date: Aug. 14, 2025

(54) EFFICIENT CELL FOR LARGE DELAY GENERATION

(71) Applicant: QUALCOMM Incorporated, San Diego, CA (US)

(72) Inventors: Xiaopeng ZHONG, Seattle, WA (US); Yuhua GUO, San Diego, CA (US)

(21) Appl. No.: 18/441,991

(22) Filed: Feb. 14, 2024

(51) Int. Cl. H03K 5/134; H03K 5/00; H03M 3/00; H04M 1/60

(52) U.S. Cl. CPC H03K 5/134; H04M 1/6008; H03K 2005/00195; H03M 3/458

(57) ABSTRACT

A delay cell includes two serial stacks of transistors. Each serial stack includes a PMOS transistor having a source coupled to a power supply node for a power supply voltage and includes an NMOS transistor having a source coupled to ground. In each serial stack, at least one diode-connected transistor is coupled between a drain of the PMOS transistor and a drain of the NMOS transistor.

### TECHNICAL FIELD

The present application relates generally delay lines and more specifically to a delay line cell for large delay generation.

### BACKGROUND

A delay circuit may be constructed using a serial chain of inverters. As the number of inverters is increased, the resulting delay is increased between an input signal and an output signal to the serial chain of inverters. But each inverter may provide only around 1 ns of delay, depending upon the process node. Should a serial chain of inverters need to provide 100 ns of delay, approximately 100 inverters would be required. Such a relatively large number of inverters consumes a substantial amount of power and demands a corresponding large amount of semiconductor die space.

### SUMMARY

In accordance with an aspect of the disclosure, a delay cell in a delay circuit is provided that includes: a first p-type metal-oxide semiconductor (PMOS) transistor having a source coupled to a power supply node for a power supply voltage; a first n-type metal-oxide semiconductor (NMOS) transistor having a source coupled to ground; a first diode-connected transistor coupled between a drain of the first PMOS transistor and a drain of the first NMOS transistor; a second PMOS transistor having a source coupled to the power supply node; a second NMOS transistor having a source coupled to ground; and a second diode-connected transistor coupled between a drain of the second PMOS transistor and a drain of the second NMOS transistor, wherein the drain of the first PMOS transistor is coupled to a gate of the second PMOS transistor, and wherein the drain of the first NMOS transistor is coupled to a gate of the second NMOS transistor.

In accordance with another aspect of the disclosure, a delay cell in a delay circuit is provided that includes: a first serial stack of three transistors including a first transistor coupled to a power supply node for a power supply voltage, a second transistor coupled to ground, and a diode-connected third transistor coupled between the first transistor and the second transistor; and a second serial stack of three transistors including a fourth transistor coupled to the power supply node for the power supply voltage, a fifth transistor coupled to ground, and a diode-connected sixth transistor coupled between the fourth transistor and the fifth transistor, wherein a node between the first transistor and the diode-connected third transistor is coupled to a gate of the fourth transistor, and wherein a node between the diode-connected third transistor and the second transistor is coupled to a gate of the fifth transistor.

Finally, in accordance with yet another aspect of the disclosure, a delay cell method is provided that includes: responding to a rising-edge transition of an input signal by switching on a first NMOS transistor having a source coupled to ground to discharge a drain of the first NMOS transistor; responding to the discharge of the drain of the first NMOS transistor by switching on a first diode-connected PMOS transistor having a drain and a gate coupled to the drain of the first NMOS transistor to discharge a source of the first diode-connected PMOS transistor to a voltage that is a transistor threshold voltage greater than a voltage of the drain of the first NMOS transistor; responding to the discharge of the source of the first diode-connected PMOS transistor by weakly switching on a second PMOS transistor to begin charging a drain of the second PMOS transistor; and responding to the charging of the drain of the second PMOS transistor by switching on a first diode-connected NMOS transistor having a drain and a gate coupled to the drain of the second PMOS transistor to charge a source of the first diode-connected NMOS transistor.

These and other advantageous features may be better appreciated through the following detailed description.

### BRIEF DESCRIPTION OF THE DRAWINGS

FIG. 1 is a diagram of a pulse generator including a delay circuit formed by a serial chain of delay cells in accordance with an aspect of the disclosure.

FIG. 2 is a circuit diagram of a rising-edge delay cell in accordance with an aspect of the disclosure.

FIG. 3 is a diagram of a delay circuit formed by a serial chain of three delay cells in accordance with an aspect of the disclosure.

FIG. 4 is a circuit diagram of a falling-edge delay cell in accordance with an aspect of the disclosure.

FIG. 5 is a circuit diagram of a dual-edge delay cell in accordance with an aspect of the disclosure.

FIG. 6 is a diagram of a sigma-delta analog-to-digital converter in which a noise-shaping SAR quantizer includes a pulse generator in accordance with an aspect of the disclosure.

FIG. 7 is a more-detailed diagram of the noise-shaping SAR quantizer and pulse generator of FIG. 6 in accordance with an aspect of the disclosure.

FIG. 8 is a flowchart for a delay cell method in accordance with an aspect of the disclosure.

FIG. 9 is a diagram of some example electronic systems including a pulse generator in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

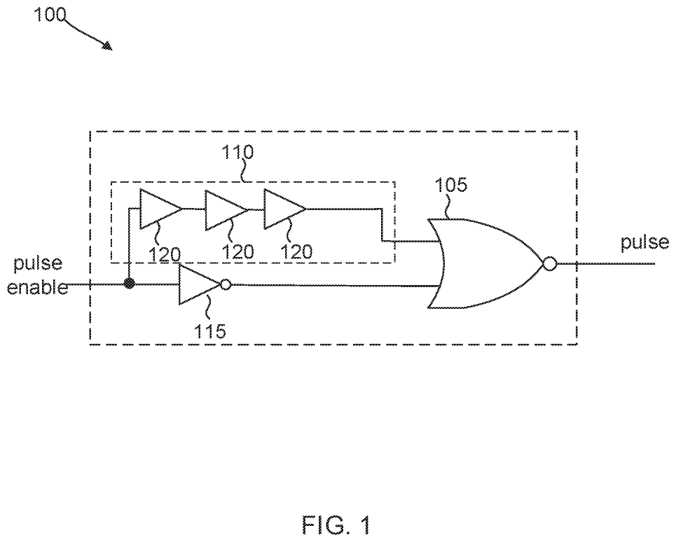

A delay circuit is disclosed that includes a serial chain of delay cells. As compared to a traditional serial chain of inverters, the resulting delay circuit is advantageously compact and has reduced power consumption. The resulting delay circuit may be used in a wide variety of applications. An example application is a pulse generator 100 as shown in FIG. 1. A pulse enable signal is delayed by a delay circuit 110 formed by a serial chain of delay cells 120 to drive a delayed version of the pulse enable signal to a first input terminal of a NOR gate 105. The pulse enable signal is also inverted by an inverter 115 to drive a second input terminal of the NOR gate 105. Suppose that a default version of the pulse enable signal is grounded. The delayed pulse signal will also be grounded in the default state whereas an inverted pulse signal from the inverter 115 is charged to a power supply voltage. A pulse signal produced by the NOR gate 105 will thus be grounded in the default state. Should the pulse enable signal be asserted to the power supply voltage, the inverter 115 will drive the second input terminal of the NOR gate 105 with a binary zero (a grounded signal). But the relatively longer delay through the delay circuit 110 results in both the input signals to the NOR gate 105 being grounded until the delay through the delay circuit 110 is completed. The pulse signal from the NOR gate 105 will thus pulse high for a pulse width that substantially equals the delay through the delay circuit 110 and then return to ground once the delay is completed.

Other applications of a delay circuit formed by a serial chain of inverters includes a non-overlapping clock generator. But regardless of the application, note the advantages of the resulting delay circuit over using a traditional serial chain of inverters. In particular, each inverter in the serial chain may provide merely around 1 ns of delay, depending upon the process node. Should the required delay be over 100 ns, more than 100 inverters may be required. But the efficient delay cell 120 provides significantly increased delay as compared to an inverter (at the same process node). To provide this delay, a diode-connected transistor is inserted between a p-type metal-oxide semiconductor (PMOS) transistor and an n-type metal-oxide semiconductor (NMOS) transistor in an inverter. Depending upon the implementation, the diode-connected transistor slows either a charging transition or a discharging transition (or both transitions) for the inverter as will be explained further herein.

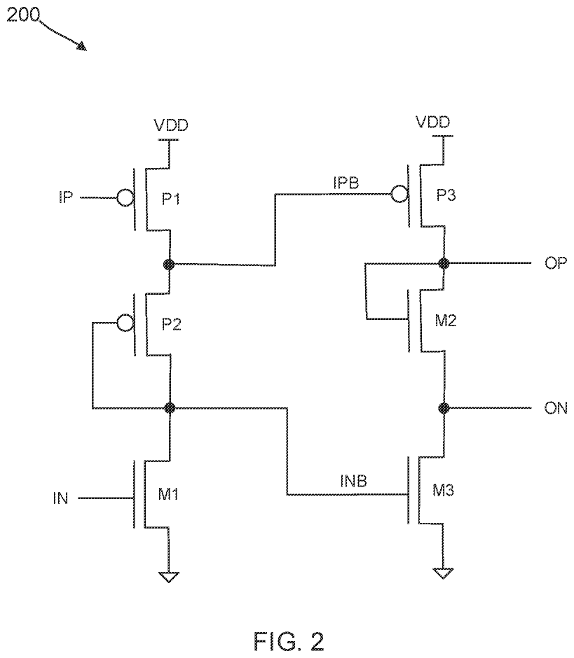

An example delay cell 200 is shown in more detail in FIG. 2. A PMOS transistor P1 has a source coupled to a node for a power supply voltage VDD and a drain connected to a source of a diode-connected PMOS transistor P2. A drain and gate of the diode-connected transistor P2 couples to a drain of an NMOS transistor M1 having a source coupled to ground. The drain of transistor M1 couples to a gate of an NMOS transistor M3 having a source coupled to ground and a drain coupled to a source of a diode-connected NMOS transistor M2. A drain and gate of the diode-connected transistor M2 couples to a drain of a PMOS transistor P3 having a source coupled to the power supply node and a gate coupled to the source of transistor P2 and also coupled to the drain of transistor P1.

The gate and drain of transistor M2 (as well as the drain of transistor P3) forms an output node for a positive output signal OP of the delay cell 200. Similarly, the drain of transistor M3 (as well as the source of transistor M2) forms an output node ON for a negative output signal ON of the delay cell 200. The gate of transistor P1 forms an input node for a positive input signal IP whereas the gate of transistor M1 forms an input node for a negative input signal IN of the delay cell 200. The drain of transistor M1 forms an internal node for a complement (INB) of the negative input signal IN. Similarly, the drain of transistor P1 forms an internal node for a complement (IPB) of the positive input signal IP. Transistors P1, P2, and M1 form a first serial stack of transistors. Similarly, transistors P3, M2, and M3 form a second serial stack of transistors.

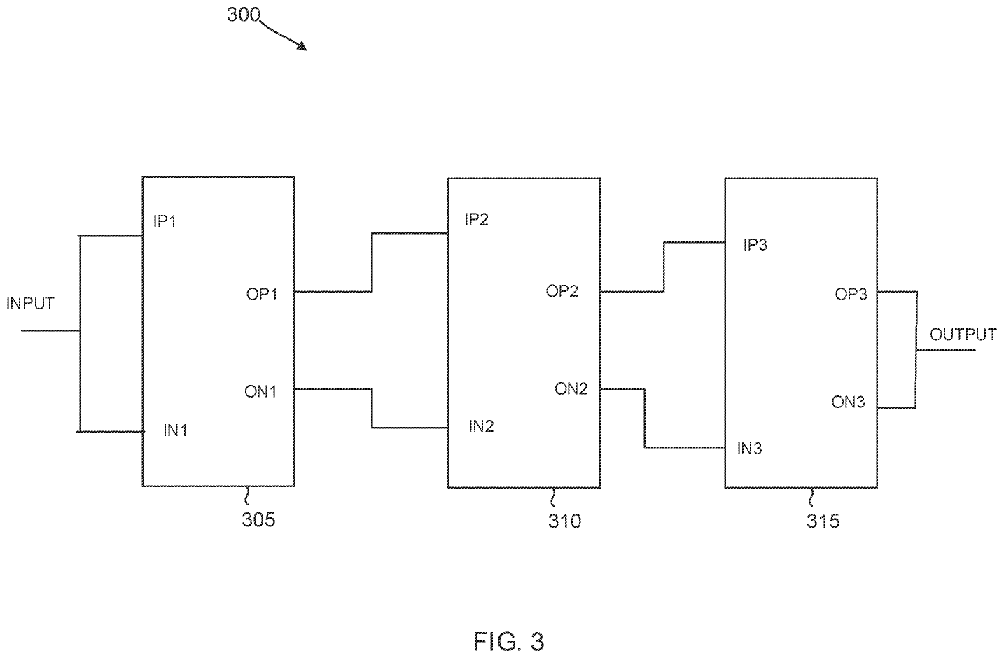

Depending upon the desired delay, delay cell 200 is duplicated and arranged in series. For example, a delay circuit 300 of FIG. 3 includes an initial delay cell 305, a second delay cell 310, and a third (and final) delay cell 315. An input signal (INPUT) forms the positive input signal (IP1) and the negative input signal (IN1) for the initial delay cell 305. The positive output signal (OP1) from the initial delay cell 305 forms the positive input signal (IP2) for the second delay cell 310. Similarly, the negative output signal (ON1) from initial delay cell 305 forms the negative input signal (IN2) for the second delay cell 310. In the same fashion, a positive output signal (OP2) from the second delay cell 310 forms the positive input signal (IP3) for the final delay cell 315 whereas a negative output signal (ON2) from the second delay cell 310 forms the negative input signal (IN3) for the final delay cell 315. Finally, a positive output signal (OP3) and a negative output signal (ON3) from the final delay cell 315 forms an output signal (OUTPUT) for the delay circuit 300.

Suppose that the input signal (INPUT) has a rising edge transition from ground to being charged to the power supply voltage VDD and that each delay cell 305, 310, and 315 is implemented as discussed for delay cell 200. In addition, suppose that transistors P1 and M1 (not illustrated) in the initial delay cell 305 had their drains coupled together to form a traditional first inverter. Similarly, suppose also that transistors P3 and M3 (not illustrated) in the initial delay cell 305 had their drains coupled together to form a traditional second inverter that was in series with the first inverter. In such a traditional arrangement of serially-coupled inverters, the rising edge of the input signal would cause transistor M1 to switch on relatively quickly to discharge its drain. This discharge of the drain of transistor M1 would in turn cause transistor P3 to switch on relatively quickly to charge its drain. But in the delay cell 200, the diode-connected transistor P2 introduces a resistance between the drains of transistors P1 and M1 that slows the discharge of the drain of transistor P1. In addition, the source of transistor P2 will remain a threshold voltage above its drain and gate voltage due to the diode connection of transistor P2. A discharge of the complement positive input signal IPB will thus be delayed with respect to charging of the negative input signal IN. In addition, transistor P3 is switched on weakly due to the complement positive input signal IPB being maintained a threshold voltage above the discharge of the drain voltage of transistor M1. The negative output signal ON1 from the initial delay cell 305 will thus have a weak rising edge transition that is delayed with respect to the rising edge transition of the input signal. This weak and delayed rising edge transition from ground towards the power supply voltage Vdd (minus a PMOS threshold voltage) for the negative output signal ON1 induces a corresponding weak and delayed rising edge transition for the negative output signal ON2 from the second delay cell 310. In turn, the weak and delayed rising edge transition for the negative output signal ON2 causes a weak and delayed rising edge transition for the output signal (OUTPUT) from the final delay cell 315. In this fashion, just the serial arrangement of the three delay cells 305, 310, and 315 introduces a relatively significant delay between the input and output signals to the delay circuit 300. In alternative implementations, just two delay cells or more than three delay cells may be arranged in serial to form a corresponding delay circuit.

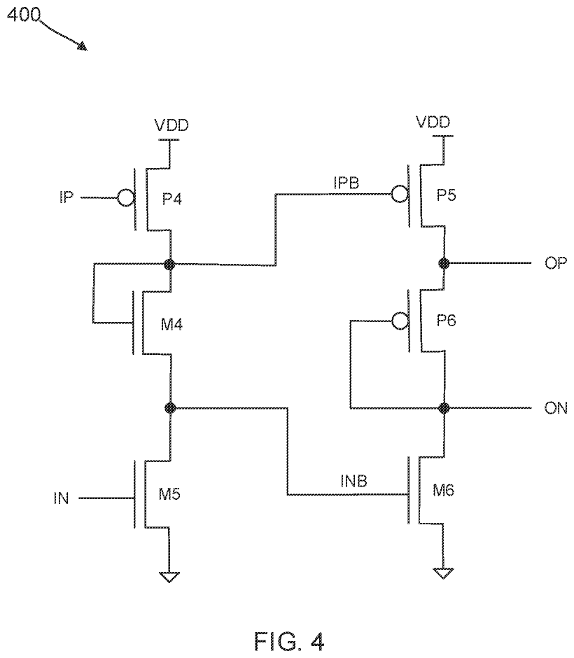

Delay cell 200 may be deemed to be rising-edge delay cell in that the rising edge of the input signal results in a delayed and relatively weak switching on of the transistor P3. In an alternative implementation, a delay cell may instead be a falling-edge delay cell. An example falling-edge delay cell 400 is shown in FIG. 4. A PMOS transistor P4 has a source coupled to a node for a power supply voltage VDD and a drain connected to a drain and to a gate of a diode-connected NMOS transistor M4. A source of the diode-connected transistor M4 couples to a drain of an NMOS transistor M5 having a source coupled to ground. The drain of transistor M5 couples to a gate of an NMOS transistor M6 having a source coupled to ground and a drain coupled to a gate and to a drain of a diode-connected PMOS transistor P6. A source of the diode-connected transistor P6 couples to a drain of a PMOS transistor P5 having a source coupled to the power supply node. A gate of the transistor P5 couples to a drain of transistor P4 and also to the drain and gate of transistor M4.

The drains of transistor P5 and the source of transistor P6 together form an output node for a positive output signal OP of the delay cell 400. Similarly, the drain of transistor M6 as well as the gate and drain of transistor P6 together form an output node for a negative output signal ON of the delay cell 400. The gate of transistor P4 forms an input node for a positive input signal IP whereas the gate of transistor M5 forms an input node for a negative input signal IN of the delay cell 400. The source of transistor M4 and the drain of transistor M5 together form an internal node for a complement (INB) of the negative input signal IN. Similarly, the drain of transistor P4 along with the gate and drain of transistor M4 together form an internal node for a complement (IPB) of the positive input signal IP.

Depending upon the desired delay, delay cell 400 is duplicated and arranged in series analogously as discussed for delay cell 200. For example, the delay cells in the delay circuit 300 of FIG. 3 may each be implemented as discussed for delay cell 400. Suppose that the input signal (INPUT) has a falling-edge transition from being charged to the power supply voltage VDD to ground. In addition, suppose that transistors P4 and M5 (not illustrated) in the initial delay cell 305 had their drains coupled together to form a traditional first inverter. Similarly, suppose also that transistors P5 and M6 (not illustrated) in the initial delay cell 305 had their drains coupled together to form a traditional second inverter that was in series with the first inverter. In such a traditional arrangement of serially-coupled inverters, the falling edge of the input signal would cause transistor P4 to switch on relatively quickly to charge its drain. This charge of the drain of transistor P4 would in turn cause transistor M6 to switch on relatively quickly to discharge its drain. But in the delay cell 400, the diode-connected transistor M4 introduces a resistance between the drains of transistors P4 and M5 that slows the charging of the source of transistor M4. In addition, the source voltage of transistor M4 will remain a threshold voltage below its drain and gate voltage due to the diode connection of transistor M4. A charging of the complement negative input signal INB will thus be delayed with respect to the falling edge of the negative input signal IN1 and maintained at a threshold voltage lower than the drain and gate voltage of transistor M4. The complement negative input signal INB will thus weakly switch on transistor M6, which causes the diode-connected transistor P6 to weakly switch on. The source voltage (OP1) of the diode-connected transistor P6 will then have a weak falling-edge transition but also be maintained a threshold voltage above the drain voltage ON1 of transistor M6. The positive output signal OP1 from the initial delay cell 305 will thus have a weak falling-edge transition that is delayed with respect to the falling-edge transition of the input signal. In addition, the positive output signal OP1 is maintained at a threshold voltage higher than the negative output signal ON1. This weak and delayed falling edge transition for the positive output signal OP1 induces a correspondingly weak and delayed falling edge transition for the positive output signal OP2 from the second delay cell 310. In turn, the weak and delayed falling edge transition for the positive output signal OP2 causes a weak and delayed falling edge transition for the output signal (OUTPUT). In this fashion, just the serial arrangement of the three delay cells 305, 310, and 315 in a falling-edge delay implementation introduces a relatively significant delay between the input and output signals to the delay circuit 300.

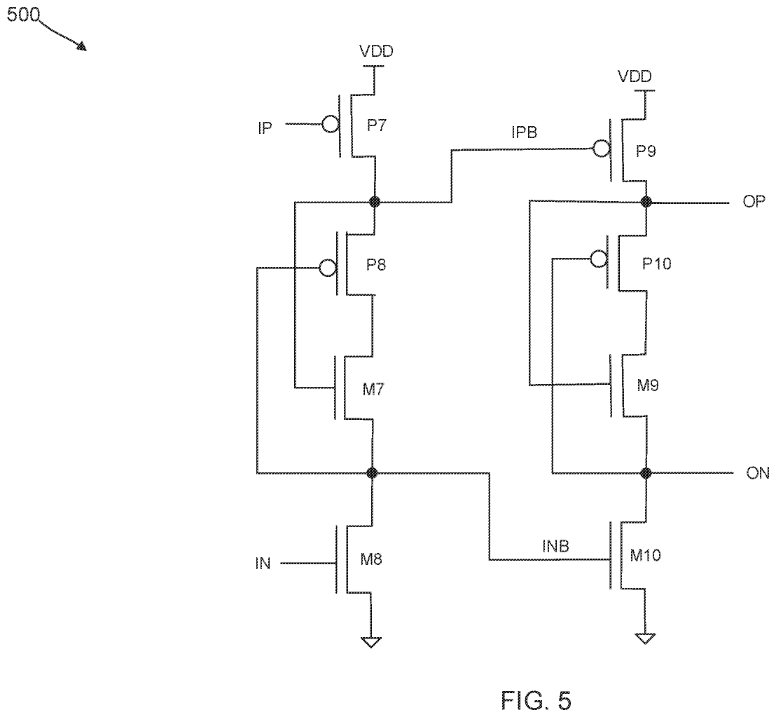

A dual-edge delay cell may be implemented that delays a response to both rising and falling edges in the input signal. An example dual-edge delay cell 500 is shown in FIG. 5. A PMOS transistor P7 has a source coupled to a node for a power supply voltage VDD and a drain connected to a source of a PMOS transistor P8. A drain of the transistor P8 couples to a drain of an NMOS transistor M7 having a source coupled to a drain of an NMOS transistor M8 having a source coupled to ground. The drain of transistor M8 couples to the gate of transistor P8. Similarly, the drain of transistor P7 couples to the gate of transistor M7. A positive input signal (IP) drives a gate of transistor P7 whereas a negative input signal (IN) drives a gate of transistor M8.

The drain of transistor M8 couples to a gate of an NMOS transistor M10 having a source coupled to ground and a drain coupled to source of an NMOS transistor M9. A drain of transistor M9 couples to a drain of a PMOS transistor P10 having a source coupled to a drain of a PMOS transistor P9. A source of transistor P9 couples to the power supply node for the power supply voltage VDD. The drain of transistor P9 couples to a gate of transistor M9. Similarly, the drain of transistor M10 couples to a gate of transistor P10. The drain of transistor P9 and the source of transistor P10 together form an output node for a positive output signal OP of the delay cell 500. Similarly, the source of transistor M9 together with the drain of transistor M10 form an output node for a negative output signal ON of the delay cell 500. The gate of transistor P7 forms an input node for a positive input signal IP whereas the gate of transistor M8 forms an input node for a negative input signal IN of the delay cell 500. The source of transistor P8 and the drain of transistor P7 together form an internal node for a complement (INB) of the positive input signal IN. The INB signal drives a gate of transistor P9. Similarly, the drain of transistor M8 along with the source of transistor M7 together form an internal node for a complement (IPB) of the positive input signal IP. The IPB signal drives a gate of transistor M10.

Referring again to delay circuit 300 of FIG. 3, note that delay cells 305, 310, and 315 may each be implemented as discussed with respect to delay cell 500. It may be seen that if the input signal has a rising edge transition, delay cell 500 functions effectively as an implementation of the delay cell 200. Conversely, should the input signal have a falling edge transition, delay cell 500 functions effectively as an implementation of delay cell 400.

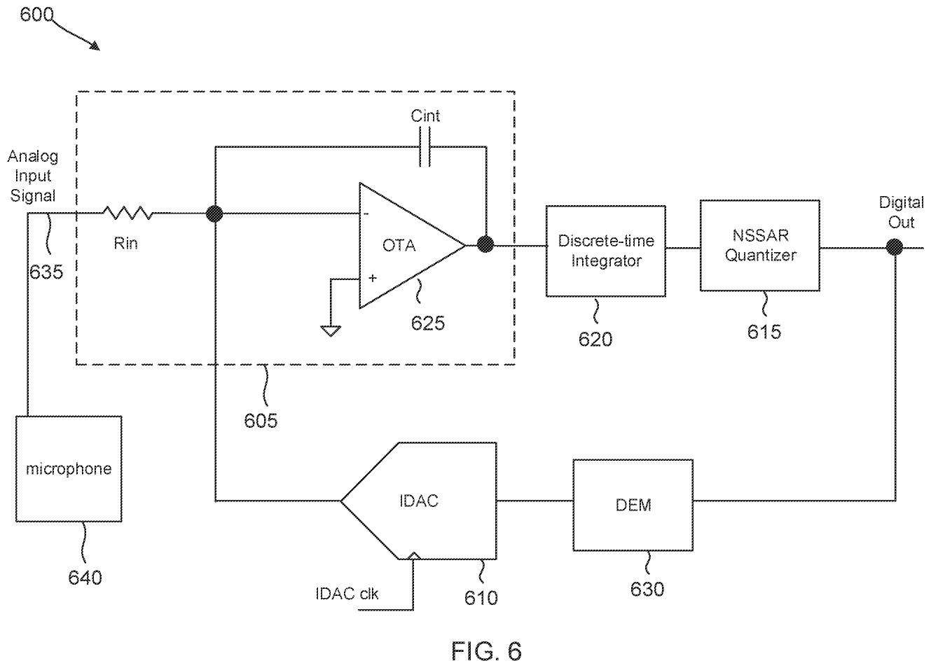

A delay circuit formed through a serial chain of delay cells as disclosed herein may be used in a wide variety of applications such as to form the delay circuit 110 in the pulse generator 100 discussed with respect to FIG. 1. The pulse generator 100 is then advantageously compact and has a low power consumption as compared to implementing the delay circuit 110 using a traditional serial chain of inverters. In one example implementation, the pulse generator 100 may be used within a noise-shaping successive-approximation-register (SAR) quantizer 615 for a sigma-delta analog-to-digital converter (ADC) 600 as shown in FIG. 6.

A first integration stage 605 is a continuous-time integration stage that integrates according to a resistor-capacitor (RC) time constant. An input resistor Rin functions as the R in the RC time constant. An input signal being quantized such as an audio signal from a micro-electromechanical system (MEMS) microphone 640 drives an input terminal 635 of the input resistor whereas another terminal of the input resistor couples to an inverting terminal of a differential amplifier such as an operational transconductance amplifier (OTA) 625. An integration capacitor that functions as the C in the RC time constant couples between the inverting terminal and an output terminal of the OTA 625. The time constant thus equals Rin*Cint, where Rin is the resistance of the input resistor and Cint is the capacitance of the integration capacitor. A feedback current digital-to-analog converter (IDAC) 610 as clocked by an IDAC clock (clk) signal also drives the inverting terminal.

A discrete-time integrator 620 integrates an output voltage signal Vout from the first integration stage 605 to provide an integrated signal that is quantized by the quantizer 615 to provide a digital output signal. After processing by a dynamic element matching (DEM) function 630, the digital output signal feeds back through the IDAC 610 to the inverting node of the OTA 625.

The noise-shaping SAR quantizer 615 includes a capacitive digital-to-analog converter (CDAC) (not shown in FIG. 6) that forms a residue during an ADC calculation cycle. The residue is the difference between the analog input signal sample being digitized and the digital output from the quantizer 615. The noise shaping advantageously frequency shifts the quantization noise from the residue out of the frequency band of interest for the input signal being digitized. The noise-shaping SAR quantizer 615 also includes a loop filter (not shown in FIG. 6) that integrates the residue to form an integration signal that is added with the input signal being digitized to form a sum signal. It is the sum signal that is ultimately digitized by the noise-shaping SAR quantizer 615.

An integration phase for the noise-shaping SAR quantizer 615 during which the integration signal is integrated by the loop filter has a duration that depends upon the ADC calculation frequency. As this frequency is decreased such as to 96 KHz, the integration phase can last up to 5 μs. Integration switches that close during the integration phase to couple the loop filter to the CDAC may then conduct leakage current. It is thus advantageous to pulse the integration switches for a shorter duration (e.g., hundreds of nano-seconds) than the actual integration phase should the integration phase be excessively long depending upon the ADC calculation frequency. But the generation of a 100 ns delay using a serial chain of traditional inverters results in a delay circuit for the corresponding pulse generator that demands a relatively large amount of semiconductor die space and increases power consumption. But the implementation of the pulse generator 100 using the delay cells disclosed herein results in a delay circuit 110 that is relatively compact and has low power consumption.

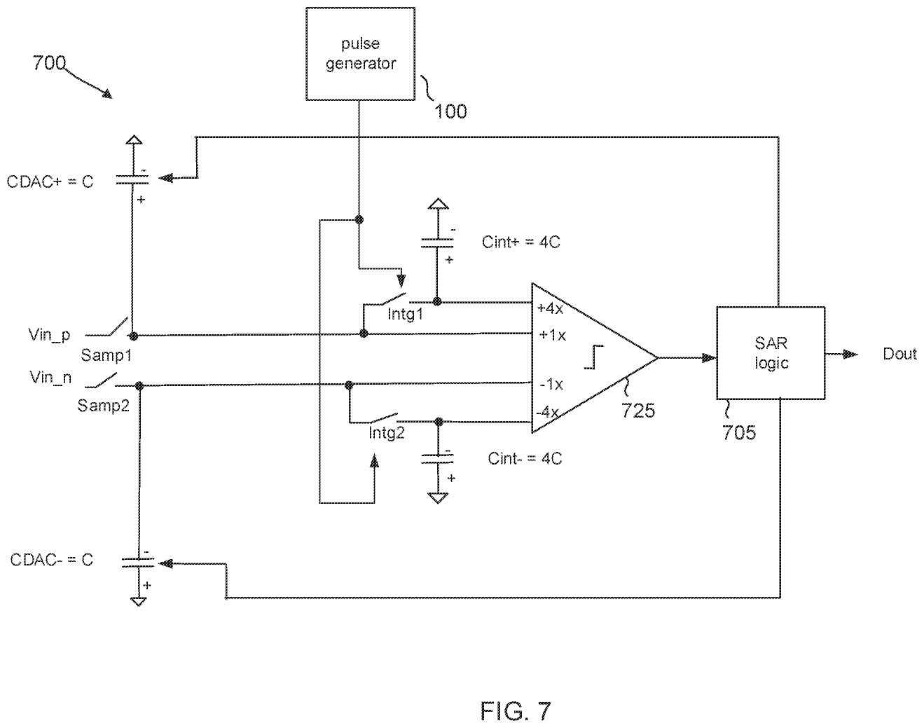

The noise-shaping SAR quantizer 615 with the pulse generator 100 to control the pulsing of integration switches is shown in more detail in FIG. 7. During an integration phase, the pulse generator 100 pulses to close a plurality of integration (Intg) switches close to couple the CDAC to a positive integration capacitor Cint+ and to a negative integration capacitor Cint−. In particular, a positive terminal of a CDAC capacitor CDAC+ (the positive output terminal of the CDAC 300) couples through a first integration switch Intg1 to a positive terminal of the Cint+ capacitor. Similarly, a negative terminal of a CDAC capacitor CDAC-couples through a second integration switch Intg2 to a negative terminal of the Cint− capacitor. After the pulsing from the pulse generator 100, the integration switches Intg1 and Intg2 are opened.

In a SAR conversion phase (which is also the amplification phase of an integration voltage in a subsequent ADC calculation cycle), a first sample switch Samp1 closes to charge the CDAC capacitor CDAC+ with a positive component Vin_p of a differential input voltage sample. Similarly, a second sample switch Samp2 closes to charge the CDAC capacitor CDAC− with a negative component Vin_n of the input voltage sample. A multi-input comparator 725 forms the summed signal as discussed earlier and compares the summed signal to a reference voltage. Based upon this comparison, a SAR-based search is formed by a SAR logic circuit 705 to adjust a capacitance of the CDAC capacitors to form a digital output signal Dout. Each CDAC capacitor has a capacitance C whereas the integration capacitors may each have a capacitance of 4C.

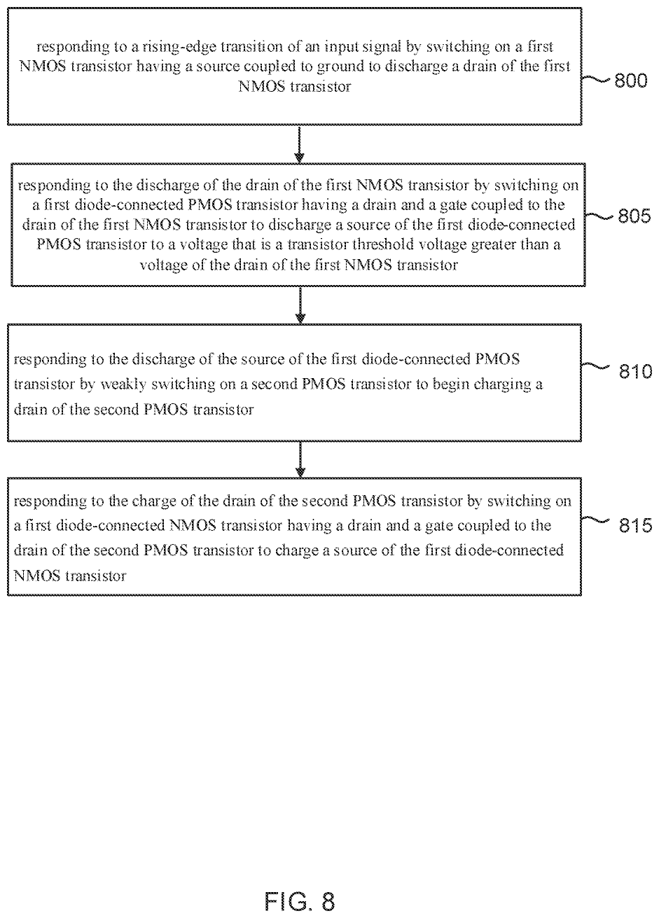

A delay cell method will now be discussed with respect to the flowchart of FIG. 8. The method includes an act 800 of responding to a rising-edge transition of an input signal by switching on a first NMOS transistor having a source coupled to ground to discharge a drain of the first NMOS transistor. The switching on of transistor M1 in delay cell 200 is an example of act 800. The method also includes an act 805 of responding to the discharge of the drain of the first NMOS transistor by switching on a first diode-connected PMOS transistor having a drain and a gate coupled to the drain of the first NMOS transistor to discharge a source of the first diode-connected PMOS transistor to a voltage that is a transistor threshold voltage greater than a voltage of the drain of the first NMOS transistor. The action of the diode-connected transistor P2 in the delay cell 200 is an example of act 805. In addition, the method includes an act 810 of responding to the discharge of the source of the diode-connected PMOS transistor by weakly switching on a second PMOS transistor to begin charging a drain of the second PMOS transistor. The delayed rising-edge transition of the positive output signal OP as discussed for delay cell 200 is an example of act 810. Finally, the method includes an act 815 of responding to the charging of the drain of the second PMOS transistor by switching on a first diode-connected NMOS transistor having a drain and a gate coupled to the drain of the second PMOS transistor to charge a source of the first diode-connected NMOS transistor. The delayed rising-edge transition of the negative output signal ON as discussed for delay cell 200 is an example of act 815.

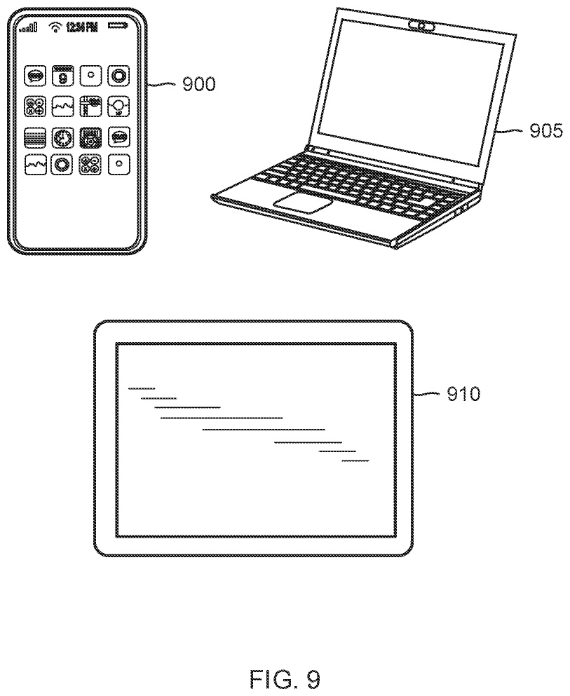

A delay circuit formed by serial chain of delay cells as disclosed herein may be incorporated in a wide variety of electronic systems. For example, as shown in FIG. 9, a cellular telephone 900, a laptop computer 905, and a tablet PC 910 may all include an analog-to-digital converter that functions to process an audio signal from a micro-electromechanical system (MEMS) microphone in which the integration switches are pulsed on according to a pulse generator including a delay circuit in accordance with the disclosure. Other exemplary electronic systems such as an earbud, a music player, a video player, a communication device, and a personal computer may also be configured with a delay circuit constructed in accordance with the disclosure.

The disclosure will now be summarized through the following example clauses:

Clause 1. A delay cell in a delay circuit, comprising:
a first p-type metal-oxide semiconductor (PMOS) transistor having a source coupled to a power supply node for a power supply voltage;
a first n-type metal-oxide semiconductor (NMOS) transistor having a source coupled to ground;
a first diode-connected transistor coupled between a drain of the first PMOS transistor and a drain of the first NMOS transistor;
a second PMOS transistor having a source coupled to the power supply node;
a second NMOS transistor having a source coupled to ground; and
a second diode-connected transistor coupled between a drain of the second PMOS transistor and a drain of the second NMOS transistor, wherein the drain of the first PMOS transistor is coupled to a gate of the second PMOS transistor, and wherein the drain of the first NMOS transistor is coupled to a gate of the second NMOS transistor.
   Clause 2. The delay cell of clause 1, wherein the first diode-connected transistor is a PMOS transistor, and wherein the second diode-connected transistor is an NMOS transistor.
   Clause 3. The delay cell of clause 1, wherein the first diode-connected transistor is an NMOS transistor, and wherein the second diode-connected transistor is a PMOS transistor.
   Clause 4. The delay cell of clause 1, wherein the first diode-connected transistor comprises:
a third PMOS transistor having a source coupled to the drain of the first PMOS transistor; and
a third NMOS transistor having a source coupled to the drain of the first NMOS transistor and having a drain coupled to a drain of the third PMOS transistor, wherein the drain of the first NMOS transistor is coupled to a gate of the third PMOS transistor, and wherein the drain of the first PMOS transistor is coupled to a gate of the third NMOS transistor.
   Clause 5. The delay cell of clause 4, wherein the second diode-connected transistor comprises:
a fourth PMOS transistor having a source coupled to the drain of the second PMOS transistor; and
a fourth NMOS transistor having a source coupled to the drain of the second NMOS transistor and having a drain coupled to a drain of the fourth PMOS transistor, wherein the drain of the second NMOS transistor is coupled to a gate of the fourth PMOS transistor, and wherein the drain of the second PMOS transistor is coupled to a gate of the fourth NMOS transistor.
   Clause 6. The delay cell of any of clauses 1-5, wherein the delay circuit is included within a pulse generator.
   Clause 7. The delay cell of clause 6, wherein the pulse generator includes:
an input node for an input signal to the pulse generator;
a NOR gate configured to generate an output signal for the pulse generator, wherein the delay circuit is coupled between the input node and a first input terminal to the NOR gate; and
an inverter coupled between the input node and a second input terminal to the NOR gate.
   Clause 8. The delay cell of any of clauses 6-7, wherein the pulse generator controls a plurality of integration switches in a noise-shaping successive-approximation-register analog-to-digital converter.
   Clause 9. The delay cell of clause 8, wherein the noise-shaping successive-approximation-register analog-to-digital converter is a quantizer for a sigma-delta analog-to-digital converter.
   Clause 10. The delay cell of clause 9, wherein the sigma-delta analog-to-digital converter is configured to digitize an audio signal from a micro-electromechanical system (MEMS) microphone.
   Clause 11. The delay cell of clause 10, wherein the sigma-delta analog-to-digital converter is included within a cellular telephone.
   Clause 12. A delay cell in a delay circuit, comprising:
a first serial stack of three transistors including a first transistor coupled to a power supply node for a power supply voltage, a second transistor coupled to ground, and a diode-connected third transistor coupled between the first transistor and the second transistor; and
a second serial stack of three transistors including a fourth transistor coupled to the power supply node for the power supply voltage, a fifth transistor coupled to ground, and a diode-connected sixth transistor coupled between the fourth transistor and the fifth transistor, wherein a node between the first transistor and the diode-connected third transistor is coupled to a gate of the fourth transistor, and wherein a node between the diode-connected third transistor and the second transistor is coupled to a gate of the fifth transistor.
   Clause 13. The delay cell of clause 12, wherein the delay cell is an initial delay cell in a serial chain of delay cells in the delay circuit.
   Clause 14. The delay cell of any of clauses 12-13, wherein the diode-connected third transistor is a PMOS transistor, and wherein the diode-connected sixth transistor is an NMOS transistor.
   Clause 15. The delay cell of any of clauses 12-13, wherein the diode-connected third transistor is an NMOS transistor, and wherein the diode-connected sixth transistor is a PMOS transistor.
   Clause 16. The delay cell of any of clauses 12-15, wherein the delay circuit is included within a pulse generator.
   Clause 17. A delay cell method, comprising:
responding to a rising-edge transition of an input signal by switching on a first NMOS transistor having a source coupled to ground to discharge a drain of the first NMOS transistor;
responding to the discharge of the drain of the first NMOS transistor by switching on a first diode-connected PMOS transistor having a drain and a gate coupled to the drain of the first NMOS transistor to discharge a source of the first diode-connected PMOS transistor to a voltage that is a transistor threshold voltage greater than a voltage of the drain of the first NMOS transistor;
responding to the discharge of the source of the first diode-connected PMOS transistor by weakly switching on a second PMOS transistor to begin charging a drain of the second PMOS transistor; and
responding to the charging of the drain of the second PMOS transistor by switching on a first diode-connected NMOS transistor having a drain and a gate coupled to the drain of the second PMOS transistor to charge a source of the first diode-connected NMOS transistor.
   Clause 18. The delay cell method of clause 17, wherein the delay cell method occurs in a first delay cell, the method further comprising:
producing an output signal having a rising-edge transition in a second delay cell that is delayed with respect to the charging of the source of the first diode-connected NMOS transistor.
   Clause 19. The delay cell method of any of clauses 17-18, further comprising:
responding to a falling-edge transition of the input signal by switching on a first PMOS transistor having a source coupled to a power supply node for a power supply voltage to charge a drain of the first PMOS transistor;
responding to the charging of the drain of the first PMOS transistor by switching on a second diode-connected NMOS transistor having a drain and a gate coupled to the drain of the first PMOS transistor to charge a source of the second diode-connected NMOS transistor to a voltage that is a transistor threshold voltage less than a voltage of the drain of the first PMOS transistor;
responding to the charging of the source of the second diode-connected NMOS transistor by weakly switching on a second NMOS transistor to discharge a drain of the second NMOS transistor; and
responding to the discharge of the drain of the second NMOS transistor by weakly switching on a second diode-connected PMOS transistor having a drain and a gate coupled to the drain of the second NMOS transistor to weakly discharge a source voltage of the second diode-connected PMOS transistor.
   Clause 20. The delay cell method of clause 19, wherein the delay cell method occurs in a first delay cell, the method further comprising:
producing an output signal having a falling-edge transition in a second delay cell that is delayed with respect to the discharge of the source voltage of the second diode-connected PMOS transistor.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A delay cell in a delay circuit, comprising:
a first p-type metal-oxide semiconductor (PMOS) transistor having a source coupled to a power supply node for a power supply voltage;
a first n-type metal-oxide semiconductor (NMOS) transistor having a source coupled to ground;
a first diode-connected transistor coupled between a drain of the first PMOS transistor and a drain of the first NMOS transistor;
a second PMOS transistor having a source coupled to the power supply node;
a second NMOS transistor having a source coupled to ground; and
a second diode-connected transistor coupled between a drain of the second PMOS transistor and a drain of the second NMOS transistor, wherein the drain of the first PMOS transistor is coupled to a gate of the second PMOS transistor, and wherein the drain of the first NMOS transistor is coupled to a gate of the second NMOS transistor.

2. The delay cell of claim 1, wherein the first diode-connected transistor is a PMOS transistor, and wherein the second diode-connected transistor is an NMOS transistor.

3. The delay cell of claim 1, wherein the first diode-connected transistor is an NMOS transistor, and wherein the second diode-connected transistor is a PMOS transistor.

4. The delay cell of claim 1, wherein the first diode-connected transistor comprises:
a third PMOS transistor having a source coupled to the drain of the first PMOS transistor; and
a third NMOS transistor having a source coupled to the drain of the first NMOS transistor and having a drain coupled to a drain of the third PMOS transistor, wherein the drain of the first NMOS transistor is coupled to a gate of the third PMOS transistor, and wherein the drain of the first PMOS transistor is coupled to a gate of the third NMOS transistor.

5. The delay cell of claim 4, wherein the second diode-connected transistor comprises:
a fourth PMOS transistor having a source coupled to the drain of the second PMOS transistor; and
a fourth NMOS transistor having a source coupled to the drain of the second NMOS transistor and having a drain coupled to a drain of the fourth PMOS transistor, wherein the drain of the second NMOS transistor is coupled to a gate of the fourth PMOS transistor, and wherein the drain of the second PMOS transistor is coupled to a gate of the fourth NMOS transistor.

6. The delay cell of claim 1, wherein the delay circuit is included within a pulse generator.

7. The delay cell of claim 6, wherein the pulse generator includes:
an input node for an input signal to the pulse generator;
a NOR gate configured to generate an output signal for the pulse generator, wherein the delay circuit is coupled between the input node and a first input terminal to the NOR gate; and
an inverter coupled between the input node and a second input terminal to the NOR gate.

8. The delay cell of claim 6, wherein the pulse generator controls a plurality of integration switches in a noise-shaping successive-approximation-register analog-to-digital converter.

9. The delay cell of claim 8, wherein the noise-shaping successive-approximation-register analog-to-digital converter is a quantizer for a sigma-delta analog-to-digital converter.

10. The delay cell of claim 9, wherein the sigma-delta analog-to-digital converter is configured to digitize an audio signal from a micro-electromechanical system (MEMS) microphone.

11. The delay cell of claim 10, wherein the sigma-delta analog-to-digital converter is included within a cellular telephone.

12. A delay cell in a delay circuit, comprising:
a first serial stack of three transistors including a first transistor coupled to a power supply node for a power supply voltage, a second transistor coupled to ground, and a diode-connected third transistor coupled between the first transistor and the second transistor; and
a second serial stack of three transistors including a fourth transistor coupled to the power supply node for the power supply voltage, a fifth transistor coupled to ground, and a diode-connected sixth transistor coupled between the fourth transistor and the fifth transistor, wherein a node between the first transistor and the diode-connected third transistor is coupled to a gate of the fourth transistor, and wherein a node between the diode-connected third transistor and the second transistor is coupled to a gate of the fifth transistor.

13. The delay cell of claim 12, wherein the delay cell is an initial delay cell in a serial chain of delay cells in the delay circuit.

14. The delay cell of claim 12, wherein the diode-connected third transistor is a PMOS transistor, and wherein the diode-connected sixth transistor is an NMOS transistor.

15. The delay cell of claim 12, wherein the diode-connected third transistor is an NMOS transistor, and wherein the diode-connected sixth transistor is a PMOS transistor.

16. The delay cell of claim 12, wherein the delay circuit is included within a pulse generator.

17. A delay cell method, comprising:
responding to a rising-edge transition of an input signal by switching on a first NMOS transistor having a source coupled to ground to discharge a drain of the first NMOS transistor;
responding to the discharge of the drain of the first NMOS transistor by switching on a first diode-connected PMOS transistor having a drain and a gate coupled to the drain of the first NMOS transistor to discharge a source of the first diode-connected PMOS transistor to a voltage that is a transistor threshold voltage greater than a voltage of the drain of the first NMOS transistor;
responding to the discharge of the source of the first diode-connected PMOS transistor by weakly switching on a second PMOS transistor to begin charging a drain of the second PMOS transistor; and
responding to the charging of the drain of the second PMOS transistor by switching on a first diode-connected NMOS transistor having a drain and a gate coupled to the drain of the second PMOS transistor to charge a source of the first diode-connected NMOS transistor.

18. The delay cell method of claim 17, wherein the delay cell method occurs in a first delay cell, the method further comprising:
producing an output signal having a rising-edge transition in a second delay cell that is delayed with respect to the charging of the source of the first diode-connected NMOS transistor.

19. The delay cell method of claim 17, further comprising:
responding to a falling-edge transition of the input signal by switching on a first PMOS transistor having a source coupled to a power supply node for a power supply voltage to charge a drain of the first PMOS transistor;
responding to the charging of the drain of the first PMOS transistor by switching on a second diode-connected NMOS transistor having a drain and a gate coupled to the drain of the first PMOS transistor to charge a source of the second diode-connected NMOS transistor to a voltage that is a transistor threshold voltage less than a voltage of the drain of the first PMOS transistor;
responding to the charging of the source of the second diode-connected NMOS transistor by weakly switching on a second NMOS transistor to discharge a drain of the second NMOS transistor; and
responding to the discharge of the drain of the second NMOS transistor by weakly switching on a second diode-connected PMOS transistor having a drain and a gate coupled to the drain of the second NMOS transistor to weakly discharge a source voltage of the second diode-connected PMOS transistor.

20. The delay cell method of claim 19, wherein the delay cell method occurs in a first delay cell, the method further comprising:
producing an output signal having a falling-edge transition in a second delay cell that is delayed with respect to the discharge of the source voltage of the second diode-connected PMOS transistor.
